(19) United States
(12) Patent Application Publication
(10) Pub. No.: US 2003/0075356 A1
(43) Pub. Date: Apr. 24, 2003

(54) Electronic device and method of manufacturing the same

(76) Inventor: Kenichi Horie, Machida-Shi (JP)

Correspondence Address: US Philips Corporation, Intellectual Property Department, 580 White Plains Road, Tarrytown, NY, 10591, US

(21) Appl. No.: 10/257,205

(22) PCT Filed: Feb. 14, 2002
(86) PCT No.: PCT/IB02/00452

(30) Foreign Application Priority Data
Feb. 16, 2001 (JP) 2001-40309

(51) Int. Cl. H05K 1/03

(52) U.S. Cl. 174/256

(57) ABSTRACT

It is an object of the invention to provide an electronic device in which a passive element with an excellent element characteristic is embedded and a method of manufacturing the same. It is another object of the invention to provide an electronic device which makes miniaturization thereof possible and a method of manufacturing the same.

A body (10) and a functional block (30) are stuck together by accommodating the functional block (30) in an opening of green ceramic sheets and then sintering those sheets. A temperature for sintering sheets to constitute a dielectric portion (31) of the functional block (30) can be different from that for sintering a raw material of a ceramic material to constitute a dielectric portion (12) of the body (10). Flexibility in selecting a material of the dielectric portion (31) can be extended and a material with a low dielectric constant can be selected for the dielectric portion (31). A dielectric constant of the ceramic material of the functional block (30) can be higher to realize miniaturization of the functional block (30). Since conductor patterns of the functional block (30) can be formed by means of thin film technologies, a three-dimensional appearance is given to edges of the conductor patterns, thereby the functional block (30) with a high Q-value can be embedded in the body (10).

The present invention relates to an electronic device comprising a body which has a plurality of laminated layers and a conductor pattern formed at least at a part of the layers, and it also relates to a method of manufacturing the electronic device.

Recently, in the area of electronic equipment such as mobile communications apparatuses, as demands for miniaturization has become stronger, technologies for improving a packing density of their parts have been developed more and more actively. For modules, such as mobile phones, which comprise radio frequency (RF) circuits, methods for manufacturing a multi-layered substrate in which such passive elements as capacitors, inductors and resonators are embedded by means of laminating a plurality of dielectric layers formed with patterns of the passive elements have received attention since these are expected to bring a higher element density.

Conventionally, multi-layered substrates made of resins and those made of ceramic materials are present as the above-mentioned substrate. The multi-layered substrates of ceramic materials are typically manufactured in such a way that wiring patterns and via holes are formed on sheets of a raw material of a ceramic material by means of screen printing and then those sheets are laminated and sintered. During this manufacturing, since metal such as copper (Cu) and silver (Ag) is used as a material for the wiring patterns, a sintering temperature of the sheets is set at low temperatures of about 900 to 1000. The multi-layered substrates manufactured through sintering at low temperature as mentioned above are often referred to as LTCC (Low-Temperature Co-fired Ceramics) substrates.

When the multi-layered substrate, however, is manufactured using the above-mentioned method, a defect that desired wiring patterns are not printed with high accuracy is caused. Such a defect, in particular, remarkably occurs at edges of the patterns. In addition, another defect that the edges of the patterns are crushed flat is also caused when the sheets with the pattern are laminated. For these reasons, with the conventional multi-layered substrates, it is difficult to make a resonator or the like inside the substrate accurately, this causing a problem that desired element characteristics such as a high Q-value for the resonator can not be obtained.

To improve a packing density of the elements in the multi-layered substrate, miniaturization of the passive elements, resonators in particular, to be incorporated in the electronic device is required. To meet with this requirement, it is necessary to use ceramic having a high dielectric constant. However, it is difficult to use any material which allows the high dielectric constant ceramic to be formed because of sintering at relatively low temperature. The material which allows the high dielectric constant ceramic to be formed, of course, may be used, but, in that case, an element having desired characteristics, for example, of a lower dielectric loss and an excellent temperature property could not be obtained again.

Such problems may be resolved by mounting the passive elements on the multi-layered substrate. With this resolution, however, an element having desired characteristics, for example, of a high Q-value for the resonator could not be realized again because a conductive material such as solder is used as an adhesive agent for mounting the passive elements.

The invention has been made in view of the above-mentioned problems and has an object to provide an electronic device of the type described in the opening paragraph in which a passive element with an excellent element characteristic is embedded and a method of manufacturing the same. It is another object of the invention to provide an electronic device which makes miniaturization thereof possible and a method of manufacturing the same.

An electronic device according to the invention is characterized in that the body comprises a receiving portion, a functional block operable as a passive element being received in the receiving portion, the functional block and the body being stuck together. It should be understood that the expression “being stuck together” used herein means they are stuck not by soldering nor bonding with an adhesive agent but by, for example, sintering or press-fitting.

With the electronic device according to the invention, since the functional block is received in the receiving portion of the body and is stuck to the body, no conductive substance is interposed between the functional block (passive element) and the body. Therefore, values (various coefficients) of the passive element are not influenced by the conductive substance. As a result, each of accuracy for the values is higher as compared with the case where the passive element is mounted on a surface of the body, thereby the passive element could have desired characteristics. In other words, according to the invention, an electronic device in which a passive element with excellent characteristics is embedded can be realized. The functional block, more specifically, is formed in such a way that a block which has been separately formed in advance is stuck to the body.

In the electronic device according to the invention, preferably, a further conductor pattern is formed on the functional block, a thickness of the further conductor pattern at its edge portions being substantially same as that at its centre. When the device has such a three-dimensional structure, an increase or an extreme increase in a current density at the edge portions of the further pattern is prevented effectively, so that a functional block with more excellent element characteristics can be realized.

The functional block may serve as a passive element for radio frequencies. More specifically, it may serve as a resonator or a filter.

In the electronic device according to the invention, preferably, the body and the functional block have dielectric portions of a ceramic material or the like, respectively, whose dielectric constants are different from each other. When the dielectric portions are constituted of a ceramic material, dielectric losses thereof are lower than those of dielectric portions of another material such as resins as well as a thickness of each dielectric portion can be controlled. It is preferable that this kind of functional block has a thickness of at least 10 μmin order to obtain desired characteristics associated with the functional block.

In the electronic device according to the invention, preferably, each dielectric portion of the body and the functional block is made of a ceramic material. With this aspect, since not only the functional block and the body are stuck but also both dielectric portions of the body and the functional block are constituted of a ceramic material, a ceramic material constituting the dielectric portion of the functional block may be different from that constituting the dielectric portion of the body. Therefore, a range of choices of ceramic to be used is extended. The dielectric constant of the dielectric portion of the functional block can be controlled easily, so that it can go higher. As a result, miniaturization of the electronic device could be realized. In this case, it is also possible to realize an electronic device in which a passive element having excellent element characteristics is embedded in the body by selecting a material with a low dielectric constant.

A method of manufacturing an electronic device according to the invention is characterized in that said method comprises steps of forming a conductor pattern on at least a part of a plurality of precursor members of a raw material of a ceramic material and an opening on at least one of the precursor members; laminating the plurality of precursor members and accommodating a functional block in the opening formed in the precursor member, the functional block having been formed with a further conductor pattern on its dielectric portion of a ceramic material and being operable as a passive element; and sintering the plurality of precursor members in which the functional block has been accommodated.

With the method of manufacturing an electronic device according to the invention, after the functional block in which the further conductor pattern was formed on its dielectric portion of a ceramic material has been accommodated in the opening formed in the precursor member, the precursor members are sintered. Therefore, the functional block may be formed separately, so that the dielectric portion of the functional block can be constituted of a ceramic material which has been sintered at a predetermined temperature. Consequently, a dielectric constant of the dielectric portion of the functional block can be easily controlled, this leading to the miniaturization of the electronic device as well as that of the passive element (functional block).

In the method of manufacturing an electronic device according to the invention, preferably, a functional block having a dielectric portion of a ceramic material which has been sintered at a first temperature is used as said functional block, the precursor members being sintered at a second temperature which is lower than the first temperature in the step of sintering the plurality of precursor members. When the temperature for sintering the precursor members is lower than that for sintering the ceramic material constituting the dielectric portion of the functional block, the functional block is little influenced by heat during sintering the precursor members, this resulting in a functional block with predetermined characteristics.

Other and further objects, features and advantages of the invention will appear more fully from the following description.

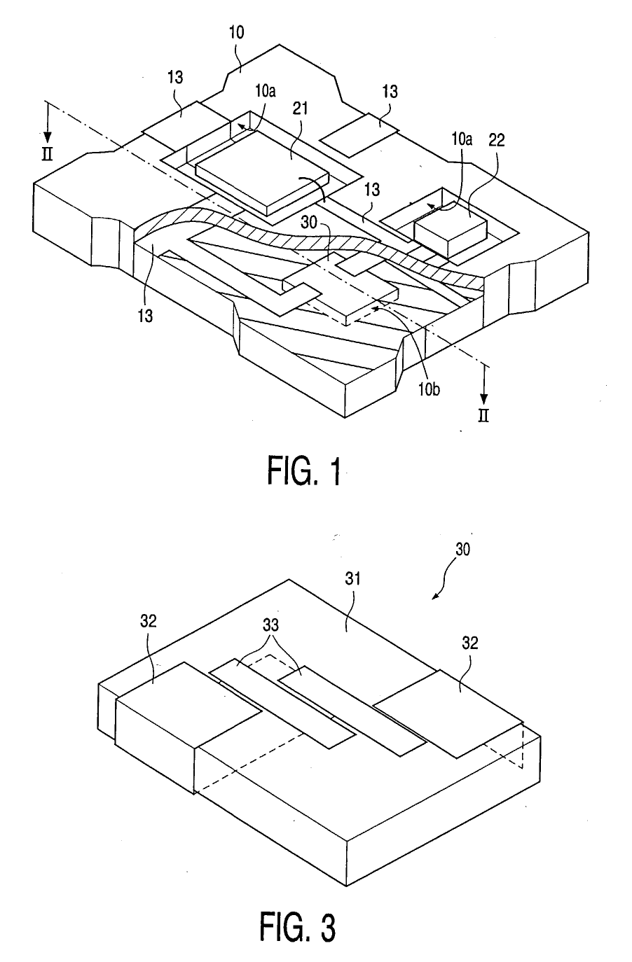

FIG. 1 is a perspective view, partly being cut away, of an electronic device according to an embodiment of the invention.

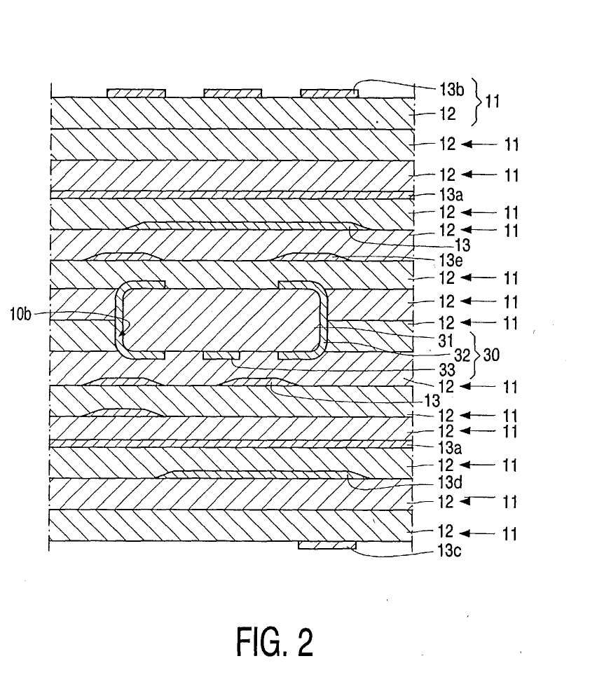

FIG. 2 is a cross-sectional view of the device taken along a line II-II of FIG. 1.

FIG. 3 is a perspective view of a functional block of the device shown in FIG. 1.

The embodiment of this invention will be described in further detail hereinafter with reference to the accompanying drawings.

Firstly, a structure of an electronic device according to an embodiment of the invention will be explained with reference to FIGS. 1 to 3.

FIG. 1 diagrammatically shows the structure of the electronic device according to the embodiment. This electronic device is to be used for, for example, a radio frequency circuit (the radio frequency in a range of, for example, about 500 MHz to 20 GHz) in a mobile communications apparatus such as a mobile phone or a bluetooth module. The electronic device comprises a body 10 having recesses 10a and an IC chip 21 and another chip 22 each disposed in the recess 10a of the body 10. It should be noted that the IC chip 21 and the other chip 22 are disposed in the recesses 10a in FIG. 1, but they may alternatively be mounted on a surface of the body 10.

FIG. 2 shows a cross-section of the device taken along a line II-II of FIG. 1. The body 10 comprises a plurality of body constituent layers 11 (14 layers in this example), each of the body constituent layers 11 being provided with a dielectric portion 12 and conductor pattern 13 formed on a surface (the upper side of the dielectric portion 12 in this example) or a back (the lower side of the dielectric portion 12 in this example) of the dielectric portion 12. The body 10 further comprises a receiving portion 10b therein, the receiving portion being formed by an opening which pass through one or more dielectric portions 12 (the seventh and the eighth dielectric portions from the top of the FIG. 2 in this example).

Each dielectric portion 12 has a thickness, for example, of 20 to 200 μm. A relative dielectric constant of a dielectric material constituting each dielectric portion 12 is, for example, 5 to 80. Specifically, the dielectric portions 12 are made, for example, of ceramic which has been sintered at a temperatures of about 850 to 1050, and more specifically, they are made, for example, of an alumina (Al₂O₃), a glass or an alumina-glass family ceramic material, a non-glass composite ceramic material, aluminium nitride (AlN) or silicon carbide (SiC). Included as the alumina family ceramic material is, for example, Al₂O₃ CaO SiO₂ MgO B₂O₃. Included as the glass family ceramic material are, for example, a mixture of MgO Al₂O₃ B₂O₃ family glass and quartz or quartz glass, and crystallized glass. Included as the alumina-glass family ceramic material are, for example, a mixture of alumina and a PbO SiO₂ B₂O₃ family glass, and a mixture of alumina and SiO₂ B₂O₃ family glass. The thicknesses and the dielectric constants for the separate dielectric portions 12 may be all equal or different.

The conductor patterns 13 include, for example, two ground patterns 13a which have a function of electrically shielding a space therebetween. The conductor patterns 13 also include a land pattern 13b to be an electrically connecting area with the IC chip 21, the chip 22 and the like, a foot pattern 13c to be an electrically connecting area with a not-shown substrate on which this electronic device is to be mounted, an inner electrode pattern 13d, a capacitor coupling electrode pattern 13e and other patterns for capacitors and/or inductors. The conductor patterns 13 are formed, for example, by means of screen printing and are composed, for example, of copper, silver, gold (Au), a silver/platinum (Pt) paste or a silver/palladium (Pd) paste. A form of each conductor pattern 13 may be differently changed in response to a requirement for a relevant electronic device. A change of the material and the thickness of each dielectric portion 12 may be made as well.

The electronic device further comprises a functional block 30 received in the receiving portion 10b of the body 10. FIG. 3 diagrammatically shows an exemplary structure of the functional block 30. The functional block 30 has been separately formed in advance and is stuck to the body 10. The functional block 30 comprises a dielectric portion 31 and conductor patterns 32 and 33 provided as further conductor patterns, which patterns are formed on a surface of the dielectric portion 31.

The functional block 30 may be either embedded fully in the receiving portion 10b of the body 10 or partially exposed outside the receiving portion 10b. The partial exposure provides an advantage that it is easy to perform trimming of the conductor patterns 32 and 33 in manufacturing, while the full embedding provides advantages that the functional block 30 resists failure, so that a reliability of the electronic device is improved in manufacturing the dielectric portion 12 (in sintering green ceramic sheets which will be described later).

The dielectric portion 31 is shaped like, for example, a rectangular sheet, a circular sheet, a ring, a prism or a cylinder. A thickness of the dielectric portion 31 is variable in accordance with the function of the functional block 30. For example, when the functional block 30 serves as a resonator or a filter, its thickness of at least 10 μm brings a higher Q-value thereof. Further, when its thickness is in range between 20 μm and 500 μm, more excellent characteristics of the functional block 30 could be obtained. With the dielectric portion 31 shaped like a rectangular sheet as shown in FIG. 3, it has dimensions, for example, of 3 mm long and 2 mm wide.

The dielectric portion 31 has a dielectric constant different from that of the dielectric portions 12 of the body 10. The materials for the dielectric portion 31 and the dielectric portions 12 are thus different from each other. The dielectric constant of the dielectric material of the dielectric portion 31 is, for example, 20 to 500. The dielectric material of the dielectric portion 31 is, for example, ceramic which has been sintered at temperatures of about 1300 to 1800. The ceramic which has been sintered at such a high temperature is preferably used because it generally has a high dielectric constant thereby the functional block 30 (dielectric portion 31) could be miniaturized. Specifically, used as a material for the dielectric portion 31 are, for example, such a titanate as denatured barium titanate Ba(Sn, Mg, Ta)TiO₃ in which part of barium in barium titanate (BaTiO₃) is substituted by tin (Sn), magnesium (Mg) or tantalum (Ta), zirconium titanate, barium titanate, calcium titanate, strontium titanate and their mixtures, alumina family ceramic such as sapphire (α-Al₂O₃) or a mixture of barium oxide (BaO), titanium oxide (TiO₂) and zirconium oxide (ZrO₂).

Each conductor pattern 32 is, for example, a coupling electrode pattern for a passive element such as a resonator, and it is capacitively coupled to the coupling electrode pattern 13e for the capacitor. Each conductor pattern 33 is, for example, a pattern for a resonator, and it is capacitively coupled to the corresponding conductor pattern 32. These conductor patterns 32 and 33 are consisted, for example, of copper, silver, gold, a mixture of silver and platinum or a mixture of silver and palladium. The thickness of each conductor pattern at its edge portions is substantially same that at its centre (for example, 10 cm). The form of each of the conductor patterns 32 and 33 might be variable again in response to a requirement for a relevant electronic device.

When the functional block 30 is adapted, for example, to perform a function as a resonator in a radio frequency circuit, a Q-value for the resonator has to be rendered as high as possible so as to increase an efficiency of the circuit. To this end, it is required to make a dielectric loss (loss factor tanδfor the complex dielectric constant) as low as possible. The above-mentioned material for the dielectric portion 31 also has a feature of the lower dielectric loss, so that the Q-value for the passive element as the resonator could become higher as well as the functional block 30 could be miniaturized as already described when such a material is used.

In this case, a functional block preformed separately is used as the functional block 30, thereby the conductor patterns 32 and 33 can be patterned on the dielectric portion 31 of the ceramic material using such thin film technology as plating and photolithography in manufacturing which process will be described later. Therefore, the predetermined thickness of each of the conductor patterns 32 and 33 is ensured, particularly at their edge portions, as already mentioned in contrast to the conductor patterns 13 (see FIG. 2) patterned using such method as screen printing. In general, when a radio frequency current flows through a conductor pattern, the current tends to flow to the edge portions of that conductor pattern intensively, so that a current density might be increased at the edge portions of the pattern. If said pattern is crushed flat at its edge portions and it has a non-three-dimensional appearance, the current density at the edge portions of the pattern might be further increased, this leading to a higher dielectric loss. In this embodiment, however, a decrease of the Q-value for the functional block 30, which decrease would be caused by said higher dielectric loss, is suppressed.

Secondly, a method of manufacturing the above-mentioned electronic device will be described.

On the one hand, a plurality of sheets (green ceramic sheets) each made of an appropriate raw material of a ceramic material to constitute the dielectric portion 12 of the body 10 and provided as a precursor member of the ceramic material are prepared first. The conductor pattern 13 is then formed on said each sheet by means of, for example, the screen printing method, and the opening to be the receiving portion 10b is formed on at least one of the sheets by means of, for example, laser punching or needle punching.

On the other hand, the dielectric portion 31 which has been sintered at a first temperature, for example, in a range of about 1300 to 1800 is prepared, and then the conductor patterns 32 and 33 are formed on the dielectric portion 31 using, for example, such thin film technology as plating and photolithographic technologies. The functional block 30 is thus obtained. In this case, since the conductor patterns 32 and 33 are formed by means of the plating method, the photolithographic method or the like, patterning can be performed with high accuracy of the trace width and the thickness of the pattern. Therefore, desired conductor patterns are obtained which have sharp edges with some thickness. If the conductor pattern 31 and 32 is formed by means of screen printing, it could not be formed as desired because the conductor is in paste form when patterning and that conductor could not set perfectly even after drying. However, there is no possibility of such a situation in this example.

Next, the predetermined number of sheets each formed with no opening are laminated, and then the predetermined number of sheets each formed with the opening are laminated on those sheets without the opening. The functional block 30 is accommodated in the openings, followed by laminating the predetermined number of further sheets so as to cover the functional block 30. Subsequently, the laminated sheets are pressed using, for example, a balance presser.

The coupling electrode pattern 13e may be set to an appropriate form in such a manner that a plurality of smaller coupling electrode patterns are provided, so that a shift of a position of the functional block 30 can be compensated. Moreover, the conductor patterns 32 may be set to have a larger size to compensate the shift as mentioned above.

After applying pressure, the plurality of laminated sheets accommodating the functional block are heated to a second temperature lower than the first temperature, thereby they are sintered. The second temperature is in a range, for example, of 850 to 1050, when the conductor patterns 13 are consisted of silver or copper. The electronic device shown in FIG. 1 is thus obtained in which device the functional block 30 is stuck to the body 10 having the dielectric portions 12 of ceramic.

A gap may be present between an interior wall of the sheets and the functional block 30 after accommodating the functional block 30 into the opening of the sheets. Since the sheets, however, generally heat-shrink when they become ceramic through sintering, the gap disappear after sintering, so that the body 10 and the functional block 30 would be stuck together.

With this embodiment, the body 10 and the functional block 30 are stuck together by accommodating the functional block 30 in the opening of the green ceramic sheets and then sintering those sheets. Therefore, the temperature for sintering sheets to constitute the dielectric portion 31 of the functional block 30 can be different from that for sintering a raw material of a ceramic material to constitute the dielectric portion 12 of the body 10, thereby flexibility in selecting a material of the dielectric portion 31 can be extended. As a result, the dielectric constant of the ceramic material of the dielectric portion 31 can be controlled easily, so that the dielectric constant of the dielectric portion 31 can be higher to realize miniaturization of the functional block 30. The functional block 30 with a high Q-value can be embedded in the body 10 by using a low dielectric loss material.

Furthermore, since the conductor patterns 32 and 33 can be formed on the dielectric portion 31 of ceramic, not green ceramic, by means of the plating method or the photolithography method, a three-dimensional appearance is given to the edges of the conductor patterns 32 and 33. Therefore, an increase in the current density is prevented at the edges of the conductor patterns 32 and 33, so that the functional block 30 with a high Q-value can be embedded in the body 10 using a low dielectric loss material.

Moreover, the electronic device is obtained in which the functional block 30 and the body 10 are stuck, in other words, in which a conductive substance is not interposed between the functional block 30 and the body 10, so that fluctuations in values, for example, of resistance or capacitance associated with the functional block 30 can be prevented. Therefore, an accuracy of each of the values can be improved as well as the functional block 30 with a high Q-value can be obtained.

Although the invention has been described with reference to the embodiment thereof, it will be understood that the invention is not limited to the above-mentioned embodiment but can be modified differently. For example, although the case where the functional block 30 serves as a resonator has been described in the above-mentioned embodiment, a functional block operable as a filter may alternatively be used. In that case, a plurality of said functional blocks which are capacitively coupled each other may be received in the receiving portion 10b of the body 10. A functional block operable as a passive element such as a filter and an inductor may be formed by making modifications to configurations of the conductor patterns 32 and 33.

Although the case where each body constituent layer 11 is provided with the conductor patterns 13 has been described in the above-mentioned embodiment, at least a part of the body 10 may alternatively be formed with the conductor patterns 13.

Although the case where the dielectric portions 12 and 31 are constituted of ceramic has been described in the above-mentioned embodiment, the present invention is applicable to the case where the dielectric portions 12 and 31 are constituted of resins. Moreover, the present invention may be applied to an electronic device comprising a magnetic portion of a magnetic material such as a compound containing ferrite or its family instead of the dielectric portion 12 and/or the dielectric portion 31.

1. An electronic device comprising a body which has a plurality of laminated layers and a conductor pattern formed at least at a part of the layers, said electronic device characterized in that the body comprises a receiving portion, a functional block operable as a passive element being received in the receiving portion, the functional block and the body being stuck together.

2. An electronic device as claimed in claim 1, characterized in that a further conductor pattern is formed on the functional block, a thickness of the further conductor pattern at its edge portions being substantially same as that at its centre.

3. An electronic device as claimed in claim 1 or 2, characterized in that the functional block is a preformed block.

4. An electronic device as claimed in any one of claims 1 to 3, characterized in that the body and the functional block have dielectric portions, respectively, whose dielectric constants are different from each other.

5. An electronic device as claimed in claim 4, characterized in that each dielectric portion of the body and the functional block is made of a ceramic material.

6. An electronic device as claimed in claim 4 or 5, characterized in that the dielectric portion of the functional block has a thickness of at least 10 micrometers.

7. An electronic device as claimed in any one of claims 1 to 6, characterized in that the functional block serves as a passive element for radio frequencies.

8. An electronic device as claimed in any one of claims 1 to 7, characterized in that the functional block serves as a resonator and/or a filter.

9. A method of manufacturing an electronic device, characterized in that said method comprises steps of:
forming a conductor pattern on at least a part of a plurality of precursor members of a raw material of a ceramic material and an opening on at least one of the precursor members;
laminating the plurality of precursor members and accommodating a functional block in the opening formed in the precursor member, the functional block having been formed with a further conductor pattern on its dielectric portion of a ceramic material and being operable as a passive element; and
sintering the plurality of precursor members in which the functional block has been accommodated.

10. A method of manufacturing an electronic device as claimed in claim 9, characterized in that a functional block having a dielectric portion of a ceramic material which has been sintered at a first temperature is used as said functional block, the precursor members being sintered at a second temperature which is lower than the first temperature in the step of sintering the plurality of precursor members.
